(19) United States
(12) Patent Application Publication
(10) Pub. No.: US 2004/0082169 A1
(43) Pub. Date: Apr. 29, 2004

(54) Deposition of barrier metal in damascene interconnects using metal carbonyl

(75) Inventors: Simon Chooi, Singapore (SG); Mei Sheng Zhou, Singapore (SG); Subhash Gupta, Singapore (SG)

Correspondence Address: GEORGE O. SAILE & ASSOCIATES, 28 DAVIS AVENUE, POUGHKEEPSIE, NY, 12603, US

(73) Assignee: Chartered Semiconductor Manufacturing Ltd.

(21) Appl. No.: 10/282,388

(22) Filed: Oct. 29, 2002

(51) Int. Cl. H01L 21/44; H01L 21/4763

(52) U.S. Cl. 438/687; 438/637; 438/643

(57) ABSTRACT

This invention relates to a method of fabrication used for semiconductor integrated circuit devices, and more specifically to the formation of single or dual damascene interconnects using a barrier metal layer of WNₓ or TaNₓ, deposited by plasma enhanced chemical vapor deposition (PECVD) using metal carbonyl precursors. By using a chemical vapor deposition (CVD) process with these alternate carbonyl precursors, many of the problems are solved, i.e., conformal coverage, gas phase particle generation, and incorporation of halogens or carbon into the film.

### BACKGROUND OF THE INVENTION

(1) Field of the Invention

This invention relates to a method of fabrication used for semiconductor integrated circuit devices, and more specifically to the formation of single or dual damascene interconnects using a barrier metal layer of WNₓ or TaNₓ, deposited by plasma enhanced chemical vapor deposition (PECVD) using metal carbonyl precursors.

(2) Description of Related Art

Titanium nitride, tantalum and tungsten nitride have been studied as barrier metals, with the most widely used barrier metal being tantalum nitride. Tungsten nitride is used as barrier metal with Cu seed layer for electroless copper deposition. Tungsten nitride can be deposited by several techniques: reactive sputtering, chemical vapor deposition (i.e., tungsten hexafluoride and ammonia) and by metalorganic chemical vapor deposition (MOCVD). Deposition of tungsten nitride by chemical vapor deposition (CVD) using tungsten hexafluoride and ammonia can lead to a reliability issue, which pertains to possible inclusion of fluorine in the film and potential gas phase particle generation during the deposition. As with tungsten nitride, tantalum nitride can also be deposited through reactive sputtering, chemical vapor deposition (CVD) (i.e., TaBr₅, nitrogen and hydrogen) and by metalorganic chemical vapor deposition (MOCVD) (i.e., TBTDET). These barrier layer films lack conformality and can result in the incorporation of bromine or carbon into the films.

Related prior art background patents will now be described in this section.

U.S. Pat. No. 5,691,235 entitled “Method of Depositing Tungsten Nitride Using a Source Gas Comprising Silicon” granted Nov. 25, 1997 to Meikle et al. describes a method of depositing WN by CVD using W carbonyl and N-containing gas. The method discloses depositing tungsten nitride using a source gas mixture having a silicon based gas, i.e., silane for depositing the tungsten nitride to overlie a deposition substrate. A non-planar storage capacitor has a tungsten nitride capacitor electrode.

U.S. Pat. No. 5,429,989 entitled “Process for Fabricating a Metallization Structure in a Semiconductor Device” granted Jul. 4, 1995 to Fiordalice et al. shows an MOCVD of W using W(CO)₆ and of WN using other metal-organo reagents. The process for fabricating a metallization structure includes the formation of an interlayer using an MOCVD deposition process. A metal-organic precursor, having as one component tungsten, is used to deposit the interlayer onto a surface region of a substrate at the bottom of an opening. The MOCVD deposition process forms a conformal layer which evenly coats all surfaces of the opening. Next, a refractory metal layer is deposited to overlie the interlayer. Because of conformal nature of the MOCVD deposition process, refractory metal layer can be formed using corrosive gasses such as tungsten hexafluoride.

U.S. Pat. No. 5,354,712 entitled “Method for Forming Interconnect Structures for Integrated Circuits” granted Oct. 11, 1994 to Ho et al. shows a copper dual damascene with WN barrier layers. A method is provided for forming interconnect structures for ULSI integrated circuits. Preferably, a barrier layer of a conductive material which forms a seed layer for metal deposition is provided selectively on the side-walls and bottom of interconnect trenches defined in a dielectric layer, and a conformal layer of metal is selectively deposited on the barrier layer within the interconnect trench.

U.S. Pat. No. 6,037,001 entitled “Method for the Chemical Vapor Deposition of Copper-Based Films” granted Mar. 14, 2000 to Kaloyeros et al. shows a Cu CVD process using WN or TaN barrier layers. A method for depositing copper-based films and a copper source precursor for use in the chemical vapor deposition of copper-based films are provided. The precursor includes a mixture of at least one ligand-stabilized copper (I) beta-diketonate precursor; and at least one copper(II) beta-diketonate precursor.

### SUMMARY OF THE INVENTION

It is a general object of the present invention to provide an improved method of forming barrier metals. Barrier metals in copper damascene interconnects serve an important role in preventing the diffusion of copper into the dielectric. The present art teaches the deposition of tungsten nitride and tantalum nitride in damascene interconnects using metal carbonyl as the precursors.

As a brief summary of the present invention, copper damascene interconnects are becoming increasingly common in the art of integrated circuit manufacture. In typical damascene interconnects, the trenches and vias are first patterned in one or more dielectric material layers. The barrier metal is then deposited, followed by copper seed layer, and thereafter, bulk copper is deposited by electroplating. Finally, a chemical mechanical polishing is performed to remove the excess copper over the trenches and the dielectric. This invention relates to a method of fabrication used for semiconductor integrated circuit devices, and more specifically to the formation of single or dual damascene interconnects using a barrier metal layer of WNₓ or TaNₓ, deposited by plasma enhanced chemical vapor deposition (PECVD) using metal carbonyl precursors. By using a chemical vapor deposition (CVD) process with these alternate carbonyl precursors, many of the problems are solved, i.e., conformal coverage, gas phase particle generation, and incorporation of halogens or carbon into the film.

This invention has been summarized above and described with reference to the preferred embodiments. Some processing details have been omitted and are understood by those skilled in the art. More details of this invention are stated in the “DESCRIPTION OF THE PREFERRED EMBODIMENTS” section.

### BRIEF DESCRIPTION OF THE DRAWINGS

The object and other advantages of this invention are best described in the preferred embodiments with reference to the attached drawings that include:

FIG. 1, which in cross-sectional representation illustrates the dual damascene trench/via opening.

FIG. 2, which in cross-sectional representation illustrates the barrier metal layer, copper seed layer (too thin to be shown in Figs.) with thick plated copper on top.

FIG. 3, which in cross-sectional representation illustrates the planarization of the excess material.

FIG. 4, which in cross-sectional representation illustrates electrical contact to an N⁺ doped conducting diffusion region in a semiconductor substrate.

### DESCRIPTION OF THE PREFERRED EMBODIMENTS

Barrier metals in copper damascene interconnects serve the important role of preventing the diffusion of copper into the dielectric. The present art teaches the deposition of tungsten nitride and tantalum nitride in damascene interconnects using metal carbonyl as the precursors.

As an outline of the present invention, copper damascene interconnects are becoming increasingly common in the art of integrated circuit manufacture. In typical damascene interconnects, the trenches and vias are first patterned in one or more dielectric material layers. The barrier metal is then deposited, followed by copper seed layer, and thereafter, bulk copper is deposited by electroplating. Finally, a chemical mechanical polishing is performed to remove the excess copper over the trenches and the dielectric. This invention relates to a method of fabrication used for semiconductor integrated circuit devices, and more specifically to the formation of single or dual damascene interconnects using a barrier metal layer of WNₓ or TaNₓ, deposited by plasma enhanced chemical vapor deposition (PECVD) using metal carbonyl precursors, in a thickness from between 50 to 2,000 Angstroms. By using a chemical vapor deposition (CVD) process with these alternate carbonyl precursors, many of the problems are solved, i.e., conformal coverage, gas phase particle generation, incorporation of halogens or carbon into the film.

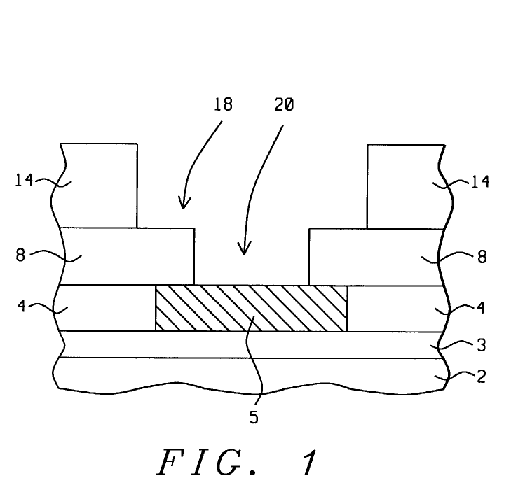

Referring to FIG. 1, in cross-sectional representation, illustrates the layers used in a dual damascene process. The substrate 2 is a single crystal silicon semiconductor. Some of the other material layers provided in FIG. 1, are as follows: semiconductor substrate 2 which includes but is not restricted to monocrystalline silicon, silicon-on-insulator (SOI) and silicon-germanium (SiGe), and patterned conducting metal wiring 5 (embedded in an insulator, which is not shown in cross-sectional FIGS.). The semiconductor substrate 2 should be understood to possibly include: one or more layers of insulating material and/or conductive material and one or more active and/or passive devices, formed in or over the substrate, or the like, and one or more interconnect structures, such as, vias, contacts, trenches, metal wiring, with a single or dual damascene formed according to the present invention or other methods known in the art. Next, a blanker of first insulating layer 3, an interlevel dielectric, is provided over the semiconductor substrate. Interconnect wiring 5, conducting line, is provided, which is patterned and embedded in a second insulating layer 4. Next, a third layer of insulator 8 is deposited over the patterned metal wiring 5 and over the second insulating layer 4. Finally, a fourth layer of insulator 14 is deposited over the third layer of insulator 8. An optional insulating layer, acting as an etch stop layer during the etching of the third insulator, can be deposited between the second insulator layer 8 and the third insulator layer 14. Also, an optional insulating cap layer, acting as a CMP stop during the polishing of copper, can also be deposited over the third insulating layer.

The third layer of insulator 8 and the fourth layer of insulator 14 are then patterned and reactive ion etched (RIE) forming trench 18 (arrow) and via 20 (arrow) openings. Many photolithographic processes can be employed to pattern the trench/via opening. The via hole can be 0.01 to 1 microns and the trench can be 0.3 um to several microns. Aspect ratio can range from 1:1 to 50:1.

Interlevel dielectric, or more correctly inter-metal dielectric, is silicon oxide, deposited using PECVD or HDP-CVD with TEOS as one of the precursors in the thickness range from 2,000 Å to 12,000 Angstroms. The silicon oxide can be un-doped or doped (e.g., with fluorine, or phosphorus, or carbon). The trench/via build types of insulating material are the following: (a) undoped silicon oxide (b) doped silicon oxide (c) organic polymer (d) porous or non-porous entity of the above. The process deposition method of these materials are the following: chemical vapor deposition, or spin-coating followed by baking in ovens and curing in furnaces.

TABLE I

| DEP. OF WNₓ | DEP. OF TaNₓ |
|---|---|
| W(CO)₆ + NH₃ | Ta(CO)₄Cₚ + NH₃ |
| W(CO)₆ + N₂/H₂ | Ta(CO)₄Cₚ + N₂/H₂ |
| W(CO)₆ + N₂H₂ | Ta(CO)₄Cₚ + N₂H₂ |
| W(CO)₆ + NO | Ta(CO)₄Cₚ + NO |

Note:
N₂H₂ is hydrazine and Cₚ, is cyclo-pentadiene.

Referring to Table I, examples of the carbonyl precursors that are used in the present invention are listed, both for tungsten nitride barrier layer and for tantalum nitride barrier layer. The present invention is not restricted to these carbonyl precursors. Any precursor that contains both W and CO, or Ta and CO is included, e.g., included are Ta(CO)₄H and Ta(CO)₅(pyridine). Associated with each metal-organic (MO) precursor is the reactive gas or gases: ammonia, nitrogen/hydrogen, hydrazine and nitrous oxide. Key to the method of the present invention is the fact that the dissociation energy of both the W—C O and Ta—C O bonds are low, allowing for easy dissociation. The following are the plasma enhanced chemical vapor deposition (PECVD) conditions used for both tungsten nitride and tantalum nitride barriers: source temperature between approximately 50 to 250° C., wafer or substrate temperature between approximately 200 to 450° C., chamber pressure between approximately 0.1 to 0.5 Torr, flow rate of carbonyl between approximately 1 to 30 sccm, flow rate of reactive gas or gases between approximately 50 to 1000 sccm (excluding the carrier gases), with ratios of flow rate of carbonyl to reactive gases between 1 to 1,000 and between 1,000 to 1. The barrier metal layer acts a liner in the trench/via cavity. More importantly, the barrier metal in copper damascene interconnects serves the important role of preventing the diffusion of copper into the dielectric material. Barrier metal thickness is between approximately 50 to 2,000 Angstroms.

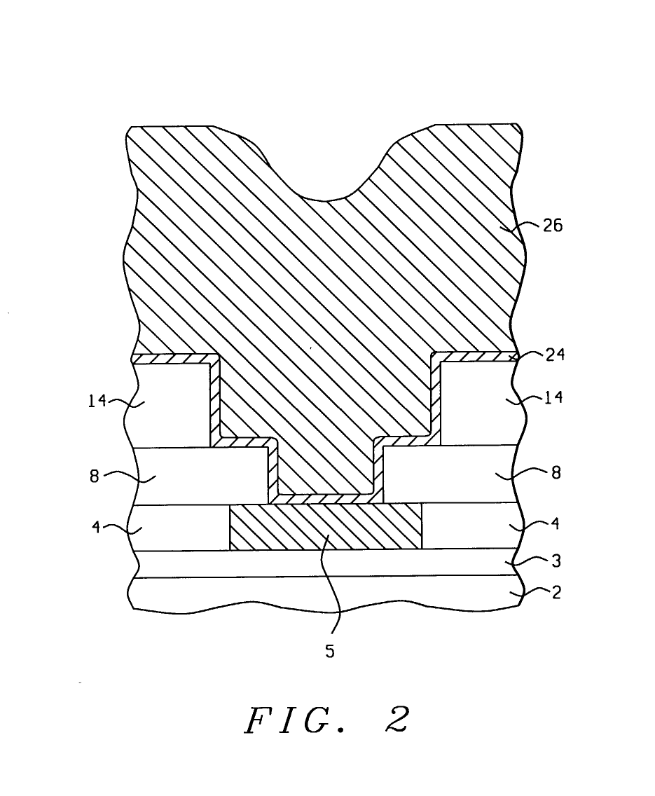

Referring to FIG. 2, in cross-sectional representation, illustrates the filling of trench/via opening or cavity with conducting metal in a dual damascene process. Firstly, the trench/via cavity is filled with a blanket deposition of barrier layer material, as described above in Table I. Referring again to FIG. 2, the barrier layer material 24 completely lines the trench/via opening or cavity, and is on the two layers of insulator, 8 and 14, respectively. Next, a thin deposition of copper seed layer (too thin to be shown in Figs.) is deposited upon the barrier layer 24. Next thick conducting copper 26 is electroplated upon the copper seed layer. The thick copper layer 24 dips into the trench/via opening or cavity. The plated thick copper deposition is approximately from 1 um to several microns in thickness. The copper is then optionally subjected to a rapid thermal annealing (RTA) treatment between 50 to 450° C. For electroplating of copper, the copper seed layer thickness is from 50 to 1,000 Angstroms thick. The thick copper top layer is from 1 to 10 microns thick. If the process requires electroplating of copper, then the barrier metal is WNₓ and TaNₓ. IF the process requires electroless plating of copper, then the barrier metal is WNₓ and no copper seed layer is required for WNₓ.

Referring to FIG. 3, in cross-sectional representation, illustrates the planarization of the excess material in the trench/via opening or cavity to form conducting interconnect wiring and conducting contact via, with inlaid copper 26 in a dual damascene process. The excess material in the thick copper layer 26 is polished back and planarized, along with the top barrier layer material 24 and copper seed layer, by chemical mechanical polish (CMP).

Note, that in the final cross-sectional view, referring to FIG. 3 again, the WN or TaN layer having a CMP rate close to copper is removed from the top surface. The WN or TaN lining the via/trench aids in containing the copper and the liner acts as a diffusion barrier. The important conducting copper line and interconnect via is shown with no dishing and they are not thinned. Hence, an important application of the present invention has been described, i.e., interconnect contact to a multi-level conducting metal line (5). Typically, the polishing process a two step CMP process relatively close polishing rates of the WN or TaN barrier layer to copper are achieved ideally and depend on the type of slurries used. A Luxtron endpoint controller is used for this process, which detects endpoint due to increased polishing friction based on an increase in drive current.

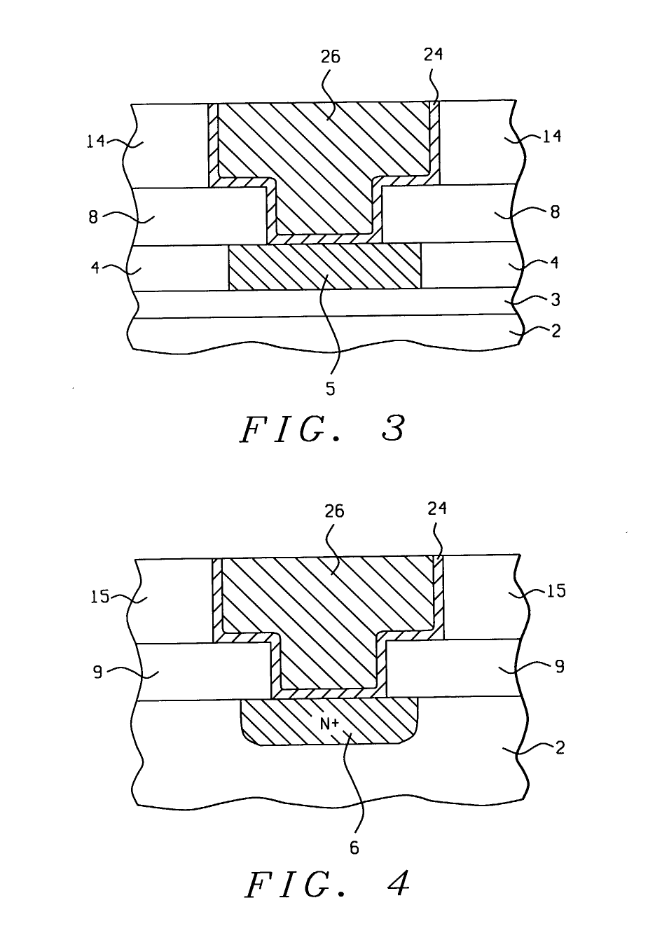

Referring to FIG. 4, which in cross-sectional representation illustrates another application of the present invention, i.e., electrical contact to an N⁺ doped conducting diffusion region 6 in a semiconductor substrate 2. Both FIG. 3 and FIG. 4 show two applications of the present invention. Only the specific areas unique to the understanding of this invention will be described in detail. Similar process steps are followed, as were outline above. However in FIG. 4, a starting silicon single crystal substrate 2 is provided with a doped conducting diffusion region, N⁺, (6) in which electrical contact is made by a barrier layer 24 and conducting copper 26, in a dual damascene trench/via process. With reference again to FIG. 4, the process sequence is as follows. First, a thick insulating layer 9 is deposited upon the substrate 2, over the doped diffusion region 6. Next a second thick insulating layer 15 is deposited over the first thick insulating layer 9. The first and second insulating layers are patterned and reactive ion etched (RIE) to form trench/via opening or cavity. Next, the barrier layer 24 material, WN or TaN (ref. to FIG. 2), is blanket deposited, and upon which a thin copper seed layer (too thin to be shown in FIGS.) is deposited on the barrier layer 24. Next, thick copper 26 is electroless deposited upon the copper seed layer. Finally, the excess material in the thick copper layer 26 is polished back and planarized without dishing, along with the top barrier layer material 24 and copper seed layer, by chemical mechanical polish (CMP). The end result of an interconnect inlaid copper 26 wiring and contact to a doped diffusion region 6, as shown in FIG. 4.

Described in the figures is a dual damascene process, but the barrier layer using carbonyl precursors also has applications for just vias and/or trenches, in a single damascene process, as a subset of the dual damascene process. This was pointed in the introduction of the specifications, second paragraph.

While the invention has been particularly shown and described with reference to the preferred embodiments thereof, it will be understood by those skilled in the art that various changes in form and details may be made without departing from the spirit and scope of the invention.

What is claimed is:

1. A method of forming conducting metal lines and interconnects in trenches and vias in the fabrication of integrated circuit devices using barrier metal layer of WNₓ or TaNₓ deposited using metal carbonyl precursors, comprising:
providing a substrate having a thin insulator layer deposited upon it;
depositing a layer of first thick insulator material upon the insulator layer;
blanket depositing a layer of second thick insulator material above the layer of the first thick insulator material;
providing patterning and etching of both the second and first thick insulator material to form trench/via opening or cavity;
depositing a blanket layer of barrier metal over the substrate;
depositing by plating conducting thick copper over the barrier;
then chemical mechanical polishing, planarizing the surface, removing excess material, forming interconnect inlaid metal wiring, in a damascene process with WNₓ or TaNₓ barriers.

2. The method of claim 1, wherein said layer of first thick insulator material is selected from the group consisting of: (a) undoped silicon oxide, (b) doped silicon oxide doped with fluorine, phosphorus, or carbon, (c) organic polymer, (d) porous or non-porous entity of the above, which are deposited by methods selecting from the group consisting of: PECVD or HDP-CVD with TEOS as one of the precursors, or spin coating, in the thickness range from 2,000 to 12,000 Angstroms, followed by an oven bake and furnace cure.

3. The method of claim 1, wherein said layer of second thick insulator material is selected from the group consisting of: (a) undoped silicon oxide, (b) doped silicon oxide doped with fluorine, phosphorus, or carbon, (c) organic polymer, (d) porous or non-porous entity of the above, which are deposited by methods selecting from the group consisting of: PECVD or HDP-CVD with TEOS as one of the precursors, or spin coating, in the thickness range from 2,000 to 12,000 Angstroms, followed by an oven bake and furnace cure.

4. The method of claim 1, wherein said barrier metal is composed of WNₓ or TaNₓ, deposited by plasma enhanced chemical vapor deposition (PECVD) with metal carbonyl precursors.

5. The method of claim 1, wherein said barrier metal composed of WNₓ or TaNₓ, is deposited by plasma enhanced chemical vapor deposition (PECVD) with metal carbonyl precursors, barrier metal with thickness from approximately 50 to 2,000 Angstroms.

6. The method of claim 1, for said tungsten nitride and said tantalum nitride are barrier metals deposited by plasma enhanced chemical vapor deposition (PECVD) with metal carbonyl precursors, the deposition (PECVD) conditions used are the following: source temperature between approximately 50 to 250° C., wafer or substrate temperature between approximately 200 to 450° C., chamber pressure between approximately 0.1 to 0.5 Torr, flow rate of carbonyl between approximately 1 to 30 sccm, flow rate of reactive gas or gases between approximately 50 to 1000 sccm (excluding the carrier gases), with ratios of flow rate of carbonyl to reactive gases between 1 to 1,000 and between 1,000 to 1, barrier metal thickness is between approximately 50 to 2,000 Angstroms.

7. The method of claim 1, a copper seed layer of copper is needed for copper plating wherein thick copper is deposited by electroplating upon a copper seed layer, which is deposited by CVD in a thickness range from 50 to 1,000 Angstroms, upon a barrier layer.

8. The method of claim 1, for said conducting thick copper is copper, deposited in a thickness range from 1 to 10 microns.

9. The method of claim 1, wherein a single damascene process is a subset of said dual damascene, with a single damascene process forming a via or a trench.

10. A method of using the dual damascene technique to form a conductive contact to a multi-level metal line and interconnection wiring pattern, in the fabrication semiconductor devices comprising:
providing said conducting line on an inter-level dielectric, which is on a semiconductor substrate;
depositing an insulator layer upon the conducting line;
depositing a layer of first thick insulator material upon the insulator layer;
blanket depositing a layer of second thick insulator material above the layer of the first thick insulator material;
providing patterning and etching of the second and first thick insulator material, insulating layer to form trench/via opening or cavity, etching down to the conducting line;
depositing a blanket layer of barrier metal over the substrate using barrier metal layer of WNₓ or TaNₓ, deposited by plasma enhanced chemical vapor deposition (PECVD) with metal carbonyl precursors;
depositing by plating conducting thick copper over the barrier metal layer;
chemical-mechanical polishing, planarizing the surface, removing excess thick copper and excess barrier metal, forming inlaid interconnect and contact via to conducting line, in a dual damascene process, with WNₓ or TaNₓ barrier metal lining the trench/via.

11. The method of claim 10, wherein said layer of first thick insulator material is selected from the group consisting of: (a) undoped silicon oxide, (b) doped silicon oxide doped with fluorine, phosphorus, or carbon, (c) organic polymer, (d) porous or non-porous entity of the above, which are deposited by methods selecting from the group consisting of: PECVD or HDP-CVD with TEOS as one of the precursors, or spin coating, in the thickness range from 2,000 to 12,000 Angstroms, followed by an oven bake and furnace cure.

12. The method of claim 10, wherein said layer of second thick insulator material is selected from the group consisting of: (a) undoped silicon oxide, (b) doped silicon oxide doped with fluorine, phosphorus, or carbon, (c) organic polymer, (d) porous or non-porous entity of the above, which are deposited by methods selecting from the group consisting of: PECVD or HDP-CVD with TEOS as one of the precursors, or spin coating, in the thickness range from 2,000 to 12,000 Angstroms, followed by an oven bake and furnace cure.

13. The method of claim 10, wherein said barrier metal is composed of WNₓ or TaNₓ, deposited by plasma enhanced chemical vapor deposition (PECVD) with metal carbonyl precursors.

14. The method of claim 10, wherein said barrier metal composed of WNₓ or TaNₓ, is deposited by plasma enhanced chemical vapor deposition (PECVD) with metal carbonyl precursors, barrier metal with thickness from approximately 50 to 2,000 Angstroms.

15. The method of claim 10, for said tungsten nitride and said tantalum nitride are barrier metals deposited by plasma enhanced chemical vapor deposition (PECVD) with metal carbonyl precursors, the deposition (PECVD) conditions used are the following: source temperature between approximately 50 to 250° C., wafer or substrate temperature between approximately 200 to 450° C., chamber pressure between approximately 0.1 to 0.5 Torr, flow rate of carbonyl between approximately 1 to 30 sccm, flow rate of reactive gas or gases between approximately 50 to 1000 sccm (excluding the carrier gases), with ratios of flow rate of carbonyl to reactive gases between 1 to 1,000 and between 1,000 to 1, barrier metal thickness is between approximately 50 to 2,000 Angstroms.

16. The method of claim 10, a copper seed layer of copper is needed for copper plating wherein thick copper is deposited by electroplating upon a copper seed layer, which is deposited by CVD in a thickness range from 50 to 1,000 Angstroms, upon a barrier layer.

17. The method of claim 10, for said conducting thick copper is copper, deposited in a thickness range from 1 to 10 microns.

18. The method of claim 10, wherein a single damascene process is a subset of said dual damascene, with a single damascene process forming a via or a trench.

19. A method of using the dual damascene technique to form a conductive contact to a semiconductor doped diffusion and interconnection wiring pattern, in the fabrication of an MOSFET comprising:
providing an active device element, doped diffusion region in a semiconductor substrate;
depositing a layer of first thick insulator material upon the insulator layer;
blanket depositing a layer of second thick insulator material above the layer of the first thick insulator material;
providing patterning and etching of the second and first thick insulator material, insulating layer to form trench/via opening or cavity, etching down to the doped diffusion region;
depositing a blanket layer of barrier metal over the substrate using barrier metal layer of WNₓ or TaNₓ, deposited by plasma enhanced chemical vapor deposition (PECVD) with metal carbonyl precursors;
depositing by plating conducting thick copper upon the barrier layer;
chemical-mechanical polishing, planarizing the surface, removing excess thick copper and excess barrier metal, forming inlaid interconnect and contact via to the doped diffusion region, in a dual damascene process, with WNₓ or TaNₓ barrier metal lining the trench/via.

20. The method of claim 19, wherein said layer of first thick insulator material is selected from the group consisting of: (a) undoped silicon oxide, (b) doped silicon oxide doped with fluorine, phosphorus, or carbon, (c) organic polymer, (d) porous or non-porous entity of the above, which are deposited by methods selecting from the group consisting of: PECVD or HDP-CVD with TEOS as one of the precursors, or spin coating, in the thickness range from 2,000 to 12,000 Angstroms, followed by an oven bake and furnace cure.

21. The method of claim 19, wherein said layer of second thick insulator material is selected from the group consisting of: (a) undoped silicon oxide, (b) doped silicon oxide doped with fluorine, phosphorus, or carbon, (c) organic polymer, (d) porous or non-porous entity of the above, which are deposited by methods selecting from the group consisting of: PECVD or HDP-CVD with TEOS as one of the precursors, or spin coating, in the thickness range from 2,000 to 12,000 Angstroms, followed by an oven bake and furnace cure.

22. The method of claim 19, wherein said barrier metal is composed of WNₓ or TaNₓ, deposited by plasma enhanced chemical vapor deposition (PECVD) with metal carbonyl precursors.

23. The method of claim 19, wherein said barrier metal composed of WNₓ or TaNₓ, is deposited by plasma enhanced chemical vapor deposition (PECVD) with metal carbonyl precursors, barrier metal with thickness from approximately 50 to 2,000 Angstroms.

24. The method of claim 19, for said tungsten nitride and said tantalum nitride are barrier metals deposited by plasma enhanced chemical vapor deposition (PECVD) with metal carbonyl precursors, the deposition (PECVD) conditions used are the following: source temperature between approximately 50 to 250° C., wafer or substrate temperature between approximately 200 to 450° C., chamber pressure between approximately 0.1 to 0.5 Torr, flow rate of carbonyl between approximately 1 to 30 sccm, flow rate of reactive gas or gases between approximately 50 to 1000 sccm (excluding the carrier gases), with ratios of flow rate of carbonyl to reactive gases between 1 to 1,000 and between 1,000 to 1, barrier metal thickness is between approximately 50 to 2,000 Angstroms.

25. The method of claim 19, a copper seed layer of copper is needed for copper plating wherein thick copper is deposited by electroplating upon a copper seed layer, which is deposited by CVD in a thickness range from 50 to 1,000 Angstroms, upon a barrier layer.

26. The method of claim 19, for said conducting thick copper is copper, deposited in a thickness range from 1 to 10 microns.

27. The method of claim 19, wherein a single damascene process is a subset of said dual damascene, with a single damascene process forming a via or a trench.
TABLE I

| DEP. OF WNₓ | DEP. OF TaNₓ |
|---|---|
| W(CO)₆ + NH₃ | Ta(CO)₄Cₚ + NH₃ |
| W(CO)₆ + N₂/H₂ | Ta(CO)₄Cₚ + N₂/H₂ |
| W(CO)₆ + N₂H₂ | Ta(CO)₄Cₚ + N₂H₂ |
| W(CO)₆ + NO | Ta(CO)₄Cₚ + NO |

Note:
N₂H₂ is hydrazine and Cₚ is cyclo-pentadiene.
